(19) United States
(12) Patent Application Publication
(10) Pub. No.: US 2015/0069585 A1
(43) Pub. Date: Mar. 12, 2015

(54) SEMICONDUCTOR DEVICE WITH AN ANGLED PASSIVATION LAYER

(71) Applicant: Taiwan Semiconductor Manufacturing Company Limited, Hsin-Chu (TW)

(72) Inventors: Chen Jui-Chun, Ji'an Township (TW); Ming-Yi Lee, Hsin-Chu City (TW); Feng-Chi Chou, Hsinchu City (TW); Shih-Han Liu, Taipei City (TW)

(21) Appl. No.: 14/024,937

(22) Filed: Sep. 12, 2013

(51) Int. Cl. H01L 23/31; H01L 21/56

(52) U.S. Cl. CPC H01L 23/3171; H01L 21/56
USPC 257/632; 438/761

(57) ABSTRACT

A semiconductor device includes a first passivation layer including a first passivation portion and a second passivation portion substantially diametrically opposite the first passivation portion. The semiconductor device includes a first corner of the first passivation portion separated a first distance from a second corner of the second passivation portion. A third corner of the first passivation portion is separated a second distance from a fourth corner of the second passivation portion. The first distance is not equal to the second distance

### BACKGROUND

In a semiconductor device, current flows through a channel region between a source region and a drain region upon application of a sufficient voltage or bias to a gate of the device. When current flows through the channel region, the device is generally regarded as being in an ‘on’ state, and when current is not flowing through the channel region, the device is generally regarded as being in an ‘off’ state.

### SUMMARY

This summary is provided to introduce a selection of concepts in a simplified form that are further described below in the detailed description. This summary is not intended to be an extensive overview of the claimed subject matter, identify key factors or essential features of the claimed subject matter, nor is it intended to be used to limit the scope of the claimed subject matter.

One or more techniques, and resulting structures, for forming a semiconductor device are provided herein.

The following description and annexed drawings set forth certain illustrative aspects and implementations. These are indicative of but a few of the various ways in which one or more aspects are employed. Other aspects, advantages, and/or novel features of the disclosure will become apparent from the following detailed description when considered in conjunction with the annexed drawings.

### DESCRIPTION OF THE DRAWINGS

Aspects of the disclosure are understood from the following detailed description when read with the accompanying drawings. It will be appreciated that elements and/or structures of the drawings are not necessarily be drawn to scale. Accordingly, the dimensions of the various features may be arbitrarily increased and/or reduced for clarity of discussion.

FIG. 1 illustrates a portion of a semiconductor device, according to an embodiment;

FIG. 2 illustrates forming a first passivation layer associated with forming a semiconductor device, according to an embodiment;

FIG. 3 illustrates a portion of a semiconductor device, according to an embodiment;

FIG. 4 illustrates patterning a first passivation layer associated with forming a semiconductor device, according to an embodiment;

FIG. 5 illustrates a portion of a semiconductor device, according to an embodiment;

FIG. 6 illustrates a portion of a semiconductor device, according to an embodiment;

FIG. 7 illustrates a portion of a semiconductor device, according to an embodiment;

FIG. 8 illustrates a portion of a semiconductor device, according to an embodiment; and

FIG. 9 illustrates a method of forming a semiconductor device, according to an embodiment.

### DETAILED DESCRIPTION

The claimed subject matter is now described with reference to the drawings, wherein like reference numerals are generally used to refer to like elements throughout. In the following description, for purposes of explanation, numerous specific details are set forth in order to provide an understanding of the claimed subject matter. It is evident, however, that the claimed subject matter may be practiced without these specific details. In other instances, structures and devices are illustrated in block diagram form in order to facilitate describing the claimed subject matter.

One or more techniques for forming a semiconductor device and resulting structures formed thereby are provided herein.

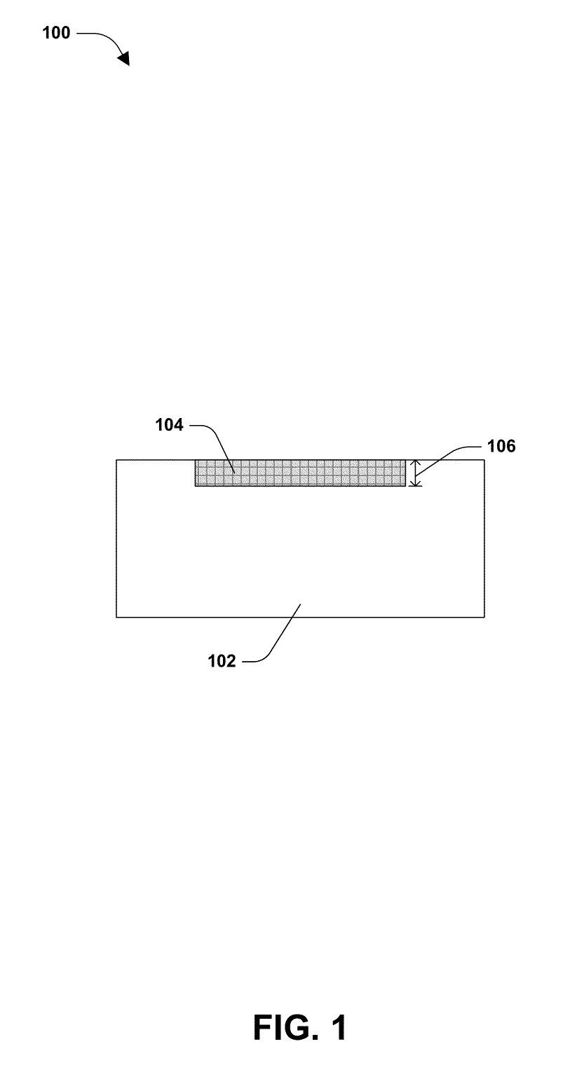

FIG. 1 is a sectional view illustrating a semiconductor device 100 according to some embodiments. In an embodiment, the semiconductor device 100 is formed upon a substrate 102. The substrate 102 comprises any number of materials, such as, for example, silicon, polysilicon, germanium, etc., alone or in combination. According to some embodiments, the substrate 102 comprises an epitaxial layer, a silicon-on-insulator (SOI) structure, etc. According to some embodiments, the substrate 102 corresponds to a wafer or a die formed from a wafer.

According to some embodiments, a metal layer 104 is formed over or within the substrate 102. The metal layer 104 includes any number of materials, including copper, aluminum, etc., alone or in combination. According to some embodiments, the metal layer 104 includes a top-metal layer structure, including a dielectric layer and copper, aluminum, etc., alone or in combination. In some embodiments, a metal layer thickness 106 of the metal layer 104 is between about 9000 angstroms (0.9 microns) to about 34000 angstroms (3.4 microns). The metal layer 104 is formed in any number of ways, such as by atomic layer deposition (ALD), chemical vapor deposition (CVD), electrochemical plating (ECP), a copper plating process, other suitable processes, etc.

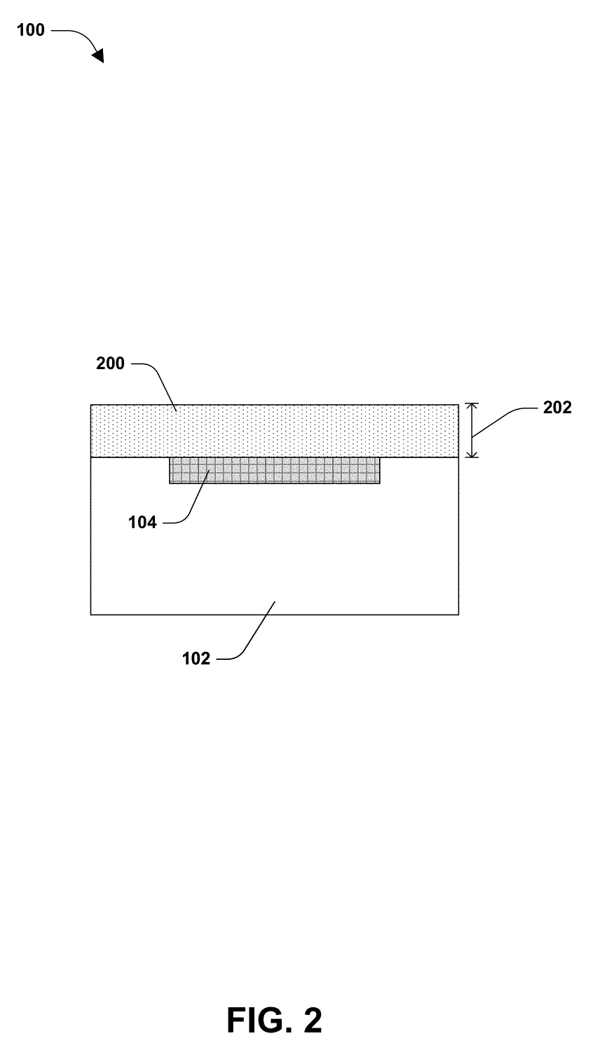

Turning to FIG. 2, in some embodiments, a first passivation layer 200 is formed over the substrate 102 and metal layer 104. The first passivation layer 200 includes any number of materials, including oxides, nitrides, silicon oxide, silicon nitride, dielectric materials, etc., alone or in combination. In some embodiments, a first passivation layer thickness 202 of the first passivation layer 200 is between about 7000 angstroms (0.7 microns) to about 10,000 angstroms (1 micron). The first passivation layer 200 is formed in any number of ways, such as by chemical vapor deposition (CVD), high-density plasma (HDP), other suitable processes, etc.

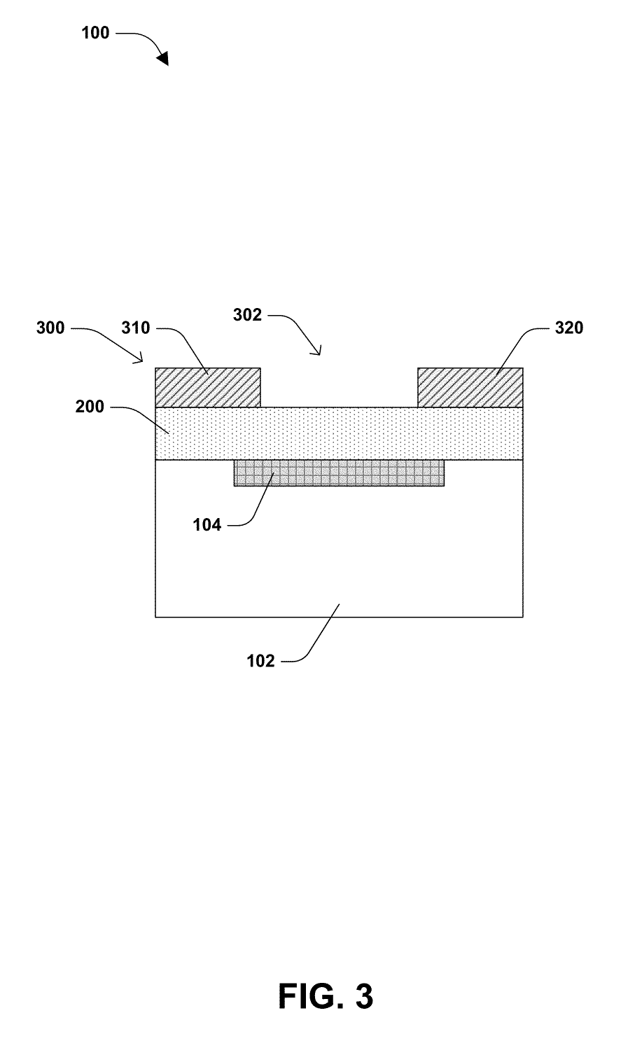

Turning to FIG. 3, in some embodiments, a mask region 300 is formed over the first passivation layer 200. The mask region 300 includes any number of materials, including oxides, nitrides, silicon oxide, silicon nitride, etc., alone or in combination. In some embodiments, the mask region 300 is patterned and etched to form a mask opening 302. In some embodiments, the mask opening 302 is formed between a first mask portion 310 and a second mask portion 320. According to some embodiments, the mask opening 302 is formed substantially over the metal layer 104. The mask opening 302 comprises any number of shapes, such as circular shapes, hexadecagonal shapes, polygonal shapes, etc.

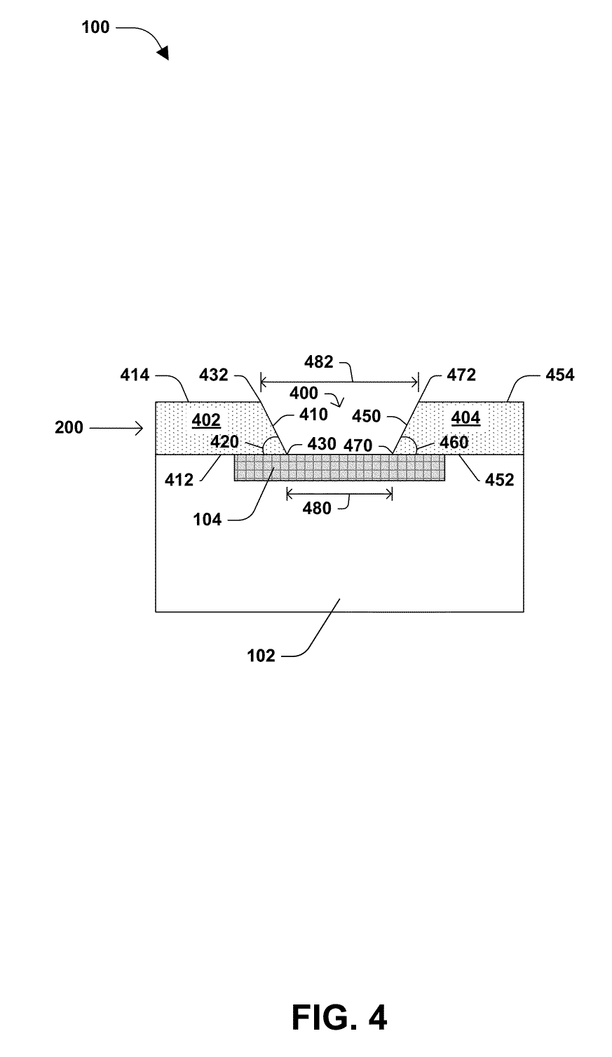

Turning to FIG. 4, a first opening 400 is formed in the first passivation layer 200. The first opening 400 is formed in any number of ways, such as by patterning the first passivation layer 200, for example. In some embodiments, patterning the first passivation layer 200 comprises etching the first passivation layer 200. In some embodiments, an etch time for etching the first opening 400 is between about 1 minute to about 5 minutes. According to some embodiments, parameters of an etching process are adjusted to achieve the profile illustrated. According to some embodiments, at least one of an etch, temperature, an etch chemistry, an etch pressure or a directionality of etchants is adjusted to achieve the profile illustrated, where more material of the passivation layer 200 is removed away from the metal layer 104 and less material of the passivation layer is removed 200 closer to the metal layer 104 to achieve the profile illustrated. In an embodiment, a first etch chemistry having a first etch selectivity with regard to material of the passivation layer 200 is initially used to remove material of the passivation layer away from the metal layer and a second etch chemistry having a second etch selectivity with regard to material of the passivation layer 200 is subsequently used to remove material of the passivation layer closer to the metal layer, where the first etch chemistry is more aggressive than the second etch chemistry such that more material is removed away from the metal layer 104 and less material is removed 200 closer to the metal layer 104 to achieve the profile illustrated. In some embodiments, at least one of an etch pressure or an etch temperature is adjusted during an etching process so that more material is removed away from the metal layer 104 and less material is removed 200 closer to the metal layer 104 to achieve the profile illustrated, where one or more etch chemistries are used during the etching process. According to some embodiments, a first passivation portion 402 of the first passivation layer 200 is substantially not etched due to being located under the first mask portion 310. According to some embodiments, a second passivation portion 404 of the first passivation layer 200 is substantially not etched due to being located under the second mask portion 320. In some embodiments, the first mask portion 310 and second mask portion 320 of the mask region 300 are removed after the first opening 400 is formed.

In some embodiments, the first passivation layer 200 comprises the first passivation portion 402 formed over the substrate 102 and over a portion of the metal layer 104. In some embodiments, the first passivation portion 402 comprises a first surface 410, a second surface 412, and a third surface 414. In an embodiment, the second surface 412 is adjacent and facing the substrate 102 and metal layer 104. In an embodiment, the third surface 414 faces away from the substrate 102 and metal layer 104, such that the second surface 412 is located in closer proximity to the substrate 102 and metal layer 104 than the third surface 414.

In some embodiments, the first surface 410 is at a first angle 420 with respect to the second surface 412. According to some embodiments, the first angle 420 is less than about 90 degrees. According to some embodiments, the first angle 420 is between about 50 degrees to about 80 degrees. In some embodiments, the first passivation layer 200 comprises a first corner 430 between the first surface 410 and the second surface 412. In some embodiments, the first passivation layer 200 comprises a third corner 432 between the first surface 410 and the third surface 414.

In some embodiments, the first passivation layer 200 comprises the second passivation portion 404 substantially diametrically opposite the first passivation portion 402. The second passivation portion 404 is formed over the substrate 102 and a portion of the metal layer 104. In some embodiments, the second passivation portion 404 comprises a fourth surface 450, a fifth surface 452, and a sixth surface 454. In an embodiment, the fifth surface 452 is adjacent and facing the substrate 102 and metal layer 104. In an embodiment, the sixth surface 454 faces away from the substrate 102 and metal layer 104 such that the fifth surface 452 is located in closer proximity to the substrate 102 and metal layer 104 than the sixth surface 454.

In some embodiments, the fourth surface 450 is at a second angle 460 with respect to the fifth surface 452. According to some embodiments, the second angle 460 is less than about 90 degrees. According to some embodiments, the second angle 460 is between about 50 degrees to about 80 degrees. In some embodiments, the first passivation layer 200 comprises a second corner 470 between the fourth surface 450 and the fifth surface 452. In some embodiments, the first passivation layer 200 comprises a fourth corner 472 between the fourth surface 450 and the sixth surface 454.

According to some embodiments, the first corner 430 of the first passivation portion 402 is separated a first distance 480 from the second corner 470 of the second passivation portion 404. In some embodiments, the first distance is between about 25,000 angstroms (2.5 microns) to about 30,000 angstroms (3 microns). According to some embodiments, the third corner 432 of the first passivation portion 402 is separated a second distance 482 from the fourth corner 472 of the second passivation portion 404. In some embodiments, the first distance 480 is less than the second distance 482. According to some embodiments, the second distance is between about 30,000 angstroms (3 microns) to about 35,000 angstroms (3.5 microns). In some embodiments, the second distance 482 is between about 1.25 to about 1.75 times as long as the first distance 480.

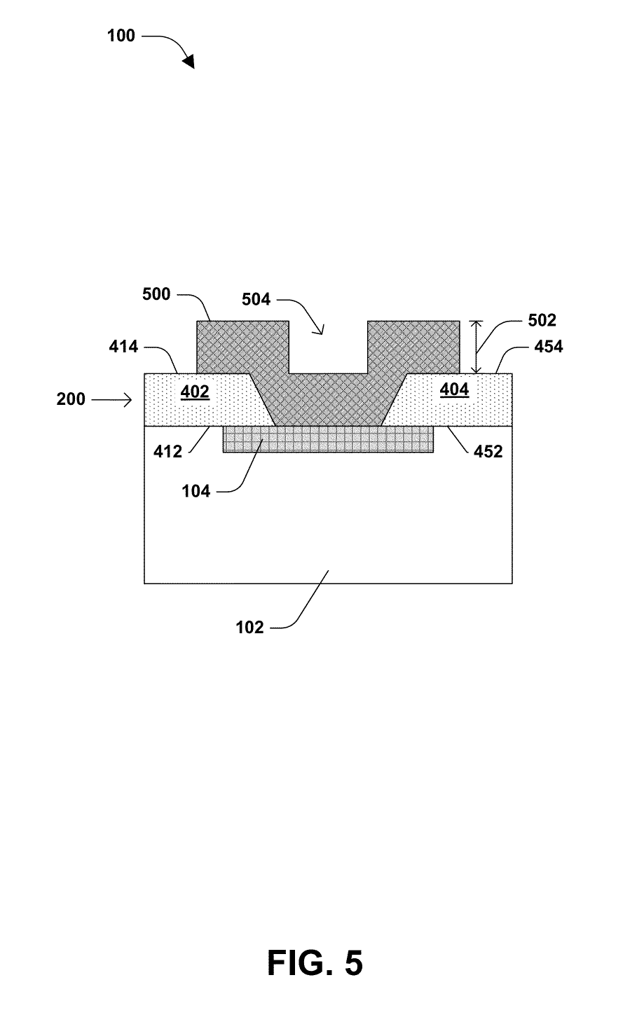

Turning to FIG. 5, in some embodiments, a pad layer 500 is formed over the first passivation portion 402 and second passivation portion 404 of the first passivation layer 200 and the metal layer 104. The pad layer 500 includes any number of materials, including aluminum, copper, etc., alone or in combination. The pad layer 500 is formed in any number of ways, such as by atomic layer deposition (ALD), chemical vapor deposition (CVD), other suitable processes, etc. According to some embodiments, a pad layer thickness 502 of the pad layer 500 is between about 14,000 angstroms (1.4 microns) to about 28,000 angstroms (2.8 microns). According to some embodiments, a pad opening 504 is formed in the pad layer 500 over the first opening 400 (illustrated in FIG. 4) of the first passivation layer 200. In some embodiments, the pad layer 500 inhibits oxidation of the metal layer 104.

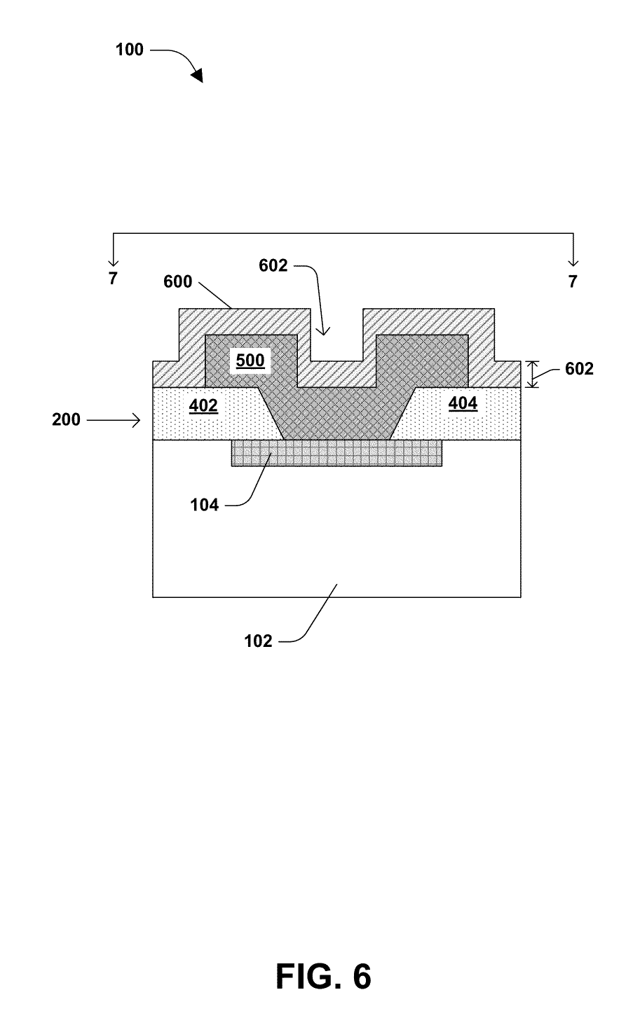

Turning to FIG. 6, in some embodiments, a second passivation layer 600 is formed over the pad layer 500. The second passivation layer 600 includes any number of materials, including oxides, nitrides, silicon oxide, silicon nitride, dielectric materials, etc., alone or in combination. In some embodiments, a second passivation layer thickness 602 of the second passivation layer 600 is between about 8000 angstroms (0.8 microns) to about 12,000 angstroms (1.2 micron). The second passivation layer 600 is formed in any number of ways, such as by chemical vapor deposition (CVD), high-density plasma (HDP), other suitable processes, etc. According to some embodiments, a passivation layer opening 602 is formed in the second passivation layer 600 over the pad opening 504 (illustrated in FIG. 5) of the pad layer 500. In some embodiments, a shape of the passivation layer opening 602 is defined by a shape of the first passivation portion 402 and second passivation portion 404 of the first passivation layer 200.

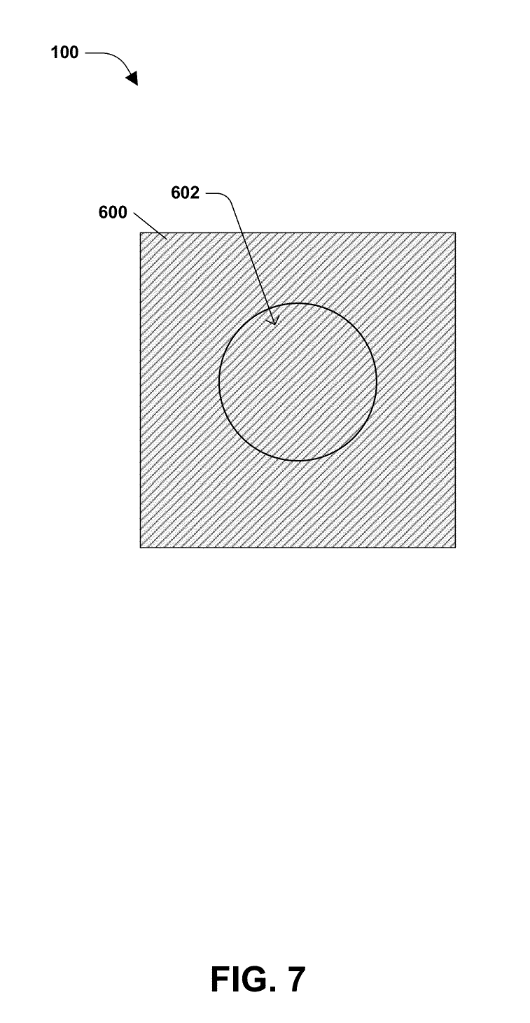

FIG. 7 is a top down view of the embodiment of FIG. 6 as viewed from a perspective indicated by lines 7-7 in FIG. 6. According to some embodiments, the passivation layer opening 602 of the second passivation layer 600 is substantially circular. In some embodiments, the shape of the passivation layer opening 602 is defined by the first passivation portion 402 and second passivation portion 404 of the first passivation layer 200.

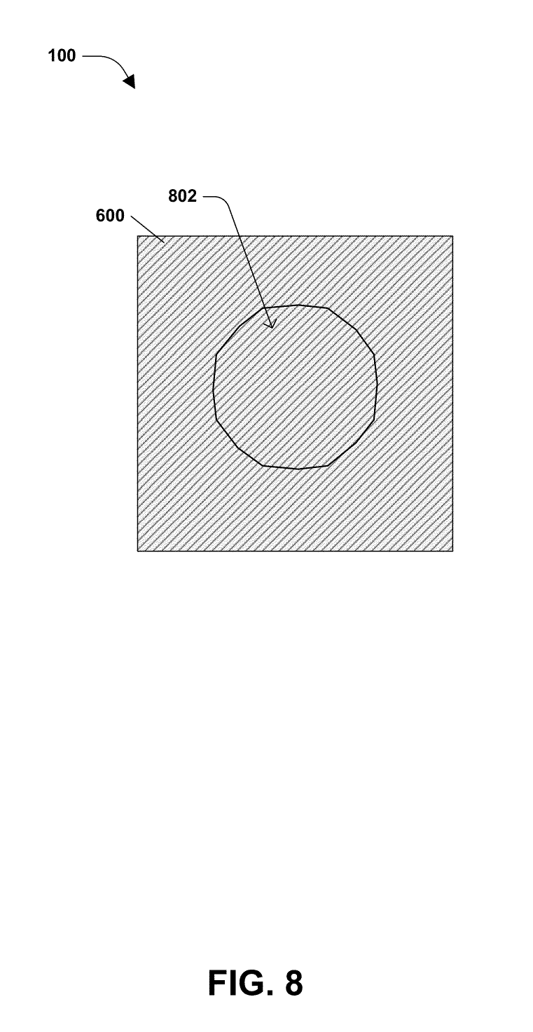

FIG. 8 is a top down view of the embodiment of FIG. 6 as viewed from a perspective indicated by lines 7-7 in FIG. 6. According to some embodiments, the second passivation layer 600 comprises a second example passivation layer opening 802. In some embodiments, the passivation layer opening 802 of the second passivation layer 600 is substantially hexadecagonal. In an embodiment, the passivation layer opening 802 comprises a sixteen sided polygon. In some embodiments, the shape of the passivation layer opening 802 is defined by the first passivation portion 402 and second passivation portion 404 of the first passivation layer 200.

According to some embodiments, the semiconductor device 100 includes the first passivation layer 200 comprising the first passivation portion 402 and second passivation portion 404. In some embodiments, the first passivation portion 402 comprises the first angle 420 that is less than about 90 degrees. In some embodiments, the second passivation portion 404 comprises the second angle 460 that is less than about 90 degrees. In some embodiments, due to the first angle 420 and second angle 460 being less than 90 degrees, the semiconductor device 100 exhibits improved coverage of the first passivation layer 200 by the pad layer 500 and second passivation layer 600. In an embodiment, this improved coverage inhibits chemical attack and oxidation of the metal layer 104. In addition, in some embodiments, the second passivation layer 600 comprises the passivation layer opening 602, 802 that is substantially circular, substantially hexadecagonal, etc. In some embodiments, these shapes of the passivation layer opening 602, 802 inhibits chemical attack and oxidation of the metal layer 104.

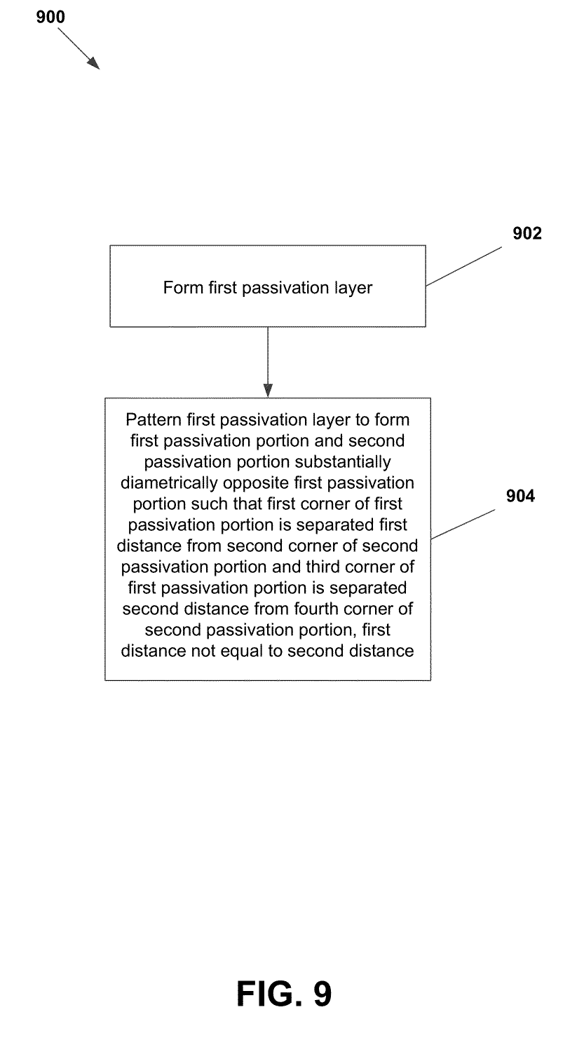

An example method 900 of forming a semiconductor device, such as semiconductor device 100, according to some embodiments, is illustrated in FIG. 9. At 902, a first passivation layer 200 is formed. At 904, the first passivation layer 200 is patterned to form a first passivation portion 402 and a second passivation portion 404 diametrically opposite the first passivation portion 402. In an embodiment, a first corner 430 of the first passivation portion 402 is separated a first distance 480 from a second corner 470 of the second passivation portion 404. In an embodiment, a third corner 432 of the first passivation portion 402 is separated a second distance 482 from a fourth corner 472 of the second passivation portion 404. In an embodiment, the first distance 480 is not equal to the second distance 482.

In an embodiment, a semiconductor device comprises a first passivation layer comprising a first passivation portion and a second passivation portion substantially diametrically opposite the first passivation portion. In an embodiment, a first corner of the first passivation portion is separated a first distance from a second corner of the second passivation portion. In an embodiment, a third corner of the first passivation portion is separated a second distance from a fourth corner of the second passivation portion. In an embodiment, the first distance is not equal to the second distance.

In an embodiment, the semiconductor device comprises a first passivation layer comprising a first passivation portion. In an embodiment, the first passivation portion comprises a first surface and a second surface. In an embodiment, the first surface is at a first angle with respect to the second surface. In an embodiment, the first angle is less than about 90 degrees.

In an embodiment, a method of forming a semiconductor device comprises forming a first passivation layer. In an embodiment, the method comprises patterning the first passivation layer to form a first passivation portion and a second passivation portion substantially diametrically opposite the first passivation portion such that a first corner of the first passivation portion is separated a first distance from a second corner of the second passivation portion. In an embodiment, a third corner of the first passivation portion is separated a second distance from a fourth corner of the second passivation portion. In an embodiment, the first distance is not equal to the second distance.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, regions, features, elements, etc. depicted herein are illustrated with particular dimensions relative to one another, such as structural dimensions and/or orientations, for example, for purposes of simplicity and ease of understanding and that actual dimensions of the same differ substantially from that illustrated herein, in some embodiments. Also, while corners or the like are illustrated as being pointed, such as where two surfaces come together, such features have, in some embodiments, a somewhat rounded contour or profile instead of a sharp or pointed profile. Additionally, a variety of techniques exist for forming the layers, regions, features, elements, etc. mentioned herein, such as implanting techniques, doping techniques, spin-on techniques, sputtering techniques, growth techniques, such as thermal growth and/or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first passivation portion and a second passivation portion generally correspond to first passivation portion A and second passivation portion B or two different or two identical passivation portions or the same passivation portion.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device comprising:
a first passivation layer comprising a first passivation portion and a second passivation portion substantially diametrically opposite the first passivation portion, a first corner of the first passivation portion separated a first distance from a second corner of the second passivation portion and a third corner of the first passivation portion separated a second distance from a fourth corner of the second passivation portion, wherein the first distance is not equal to the second distance.

2. The semiconductor device of claim 1, wherein the first passivation portion comprises a first surface and a second surface, the first surface at a first angle with respect to the second surface.

3. The semiconductor device of claim 2, wherein the first angle is less than about 90 degrees.

4. The semiconductor device of claim 2, wherein the first angle is between about 50 degrees to about 80 degrees.

5. The semiconductor device of claim 1, wherein the second passivation portion comprises a fourth surface and a fifth surface, the fourth surface at a second angle with respect to the fifth surface.

6. The semiconductor device of claim 5, wherein the second angle is less than about 90 degrees.

7. The semiconductor device of claim 5, wherein the second angle is between about 50 degrees to about 80 degrees.

8. The semiconductor device of claim 1, wherein the first distance is less than the second distance.

9. The semiconductor device of claim 1, wherein the first distance is between about 2.5 microns to about 3 microns.

10. The semiconductor device of claim 9, wherein the second distance is between about 1.25 to about 1.75 times as long as the first distance.

11. The semiconductor device of claim 1, wherein the first passivation portion and second passivation portion define a passivation layer opening that is substantially circular.

12. The semiconductor device of claim 1, wherein the first passivation portion and second passivation portion define a passivation layer opening that is substantially hexadecagonal.

13. A semiconductor device comprising:
a first passivation layer comprising a first passivation portion, the first passivation portion comprising a first surface and a second surface, the first surface at a first angle with respect to the second surface, the first angle less than about 90 degrees.

14. The semiconductor device of claim 13, wherein the first angle is between about 50 degrees to about 80 degrees.

15. The semiconductor device of claim 13, the semiconductor device comprising a second passivation portion substantially diametrically opposite the first passivation portion, wherein the second passivation portion comprises a fourth surface and a fifth surface, the fourth surface at a second angle with respect to the fifth surface.

16. The semiconductor device of claim 15, wherein the second angle is less than about 90 degrees.

17. The semiconductor device of claim 15, wherein the second angle is between about 50 degrees to about 80 degrees.

18. A method of forming a semiconductor device, comprising:
forming a first passivation layer; and
patterning the first passivation layer to form a first passivation portion and a second passivation portion substantially diametrically opposite the first passivation portion such that a first corner of the first passivation portion is separated a first distance from a second corner of the second passivation portion and a third corner of the first passivation portion is separated a second distance from a fourth corner of the second passivation portion, the first distance not equal to the second distance.

19. The method of claim 18, comprising forming a pad layer over the first passivation layer after patterning the first passivation layer.

20. The method of claim 19, comprising forming a second passivation layer over the pad layer.
